(19) United States
(12) Patent Application Publication
(10) Pub. No.: US 2008/0205149 A1
(43) Pub. Date: Aug. 28, 2008

(54) METHOD OF PROGRAMMING NON-VOLATILE MEMORY DEVICE

(75) Inventors: Duck Ju KIM, Icheon-si (KR); Jong Hyun Wang, Cheongju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/771,877

(22) Filed: Jun. 29, 2007

(30) Foreign Application Priority Data
Feb. 26, 2007 (KR) 10-2007-18963

(51) Int. Cl. G11C 7/00; G11C 11/34

(52) U.S. Cl. 365/185.18

(57) ABSTRACT

A method of programming a non-volatile memory device enables a pump in response to a first program confirm command. The pump generates a voltage. An initial page of a memory block is programmed. Subsequent intermediate pages of the memory block are programmed in response to a second program confirm command while the pump remains enabled. A final page of the memory block is programmed in response to a third program confirm command. The pump is then disabled after the final page is programmed.

### CROSS-REFERENCES TO RELATED APPLICATIONS

The present application claims priority to Korean patent application number 10-2007-18963, filed on Feb. 26, 2007, which is incorporated by reference in its entirety.

### BACKGROUND OF THE INVENTION

The present invention relates to a method of programming a non-volatile memory device, and more particularly, to a method of programming a non-volatile memory device in which a programming period can be shortened while continuously programming pages of a memory block.

Generally, a flash memory is classified as a NAND flash memory or a NOR flash memory. The NOR flash memory is configured such that memory cells are connected independently to a bit line and a word line, thereby exhibiting excellent random access characteristics. The NAND flash memory is configured such that a plurality memory cells are connected in series and one contact is provided for a cell string, thereby exhibiting excellent integration degree characteristics. Accordingly, a NAND configuration is mainly used for a highly integrated flash memory.

A well known-NAND flash memory device includes a memory cell array, a row decoder and a page buffer. The memory cell array includes a plurality of word lines arranged in rows, a plurality of bit lines arranged in columns and a plurality of cell strings corresponding to the bit lines. The word lines are divided into pages, and programming and reading are performed on a per page basis.

FIG. 1 is a flow chart showing an operation order of a continuous page programming method for a typical flash memory device. Referring to FIG. 1, a program command (CMD) to program a flash memory device is input (S101). An address of a page to be programmed is also input (S102).

Data to be programmed to the page is input (S103). An execution command for initiating the programming operation is also input (S104).

The flash memory cells are programmed using a tunneling effect via a high voltage. Accordingly, when initiating programming of a memory cell (S105), a pump for producing a high voltage is enabled (S106), and a selected page is programmed using the high voltage produced by the enabled pump (S107). After programming the memory cell, the program may be inspected (S108), and then the pump is disabled (S109).

To program the next page, a program command and an address are input (S111, S112). The data to be programmed on the page and an execution command are also input (S113, S114). A program executes to enable the pump (S115, S116). After programming the next page using the high voltage from the enabled pump (S117), an inspection may be performed (S118). The pump is then disabled (S119).

This program operation is repeated for each page until the final page is programmed (S120), and the entire memory cell is programmed.

As described above, a pump for producing a high voltage is enabled and disabled after each program operation is performed on a page. Thus, current consumption is increased, and a programming time delay results.

### SUMMARY OF THE INVENTION

A method of programming a non-volatile memory device includes program commands that are defined as either an initial program command, an intermediate program command, or a final program command. The programming method controls the programming of pages in a memory block based on the type of program command.

In one aspect, a method of programming a non-volatile memory device comprises enabling a pump in response to a first program confirm command to generate a voltage, and then programming an initial page of the memory block. An intermediate page of the memory block is programmed subsequent to the initial page in response to a second program confirm command while the pump remains enabled. A final page of the memory block is programmed in response to a third program confirm command. The pump is then disabled after the final page is programmed.

Programming the initial page of the memory block includes: inputting an initial program command, an address of the initial page, and program data; inputting the first program confirm command in response to inputting the initial program command; and programming the initial page using the voltage from the enabled pump.

Programming the intermediate page includes inputting a program command, an address of the intermediate page to be programmed, and program data; inputting the second program command; and programming the intermediate page corresponding to the address in response to inputting the second program confirm command using the voltage provided by enabled the pump.

Programming the final page includes inputting a program command, an address of the final page, and program data; inputting the third program confirm command in response to inputting the address of the final page; and programming the final page using the voltage provided by the enabled pump;.

The first, second and third program confirm commands are input differently based on which page address is input.

The programmed pages are inspected.

### BRIEF DESCRIPTION OF THE DRAWINGS

The accompanying drawings, which are included to provide a better understanding of the invention and are incorporated in and constitute a part of this application, illustrate embodiments of the invention, and together with the description serve to explain the principle of the invention. In the drawings:

FIG. 1 is a flow chart showing an operation order of a continuous page program method for a typical flash memory device;

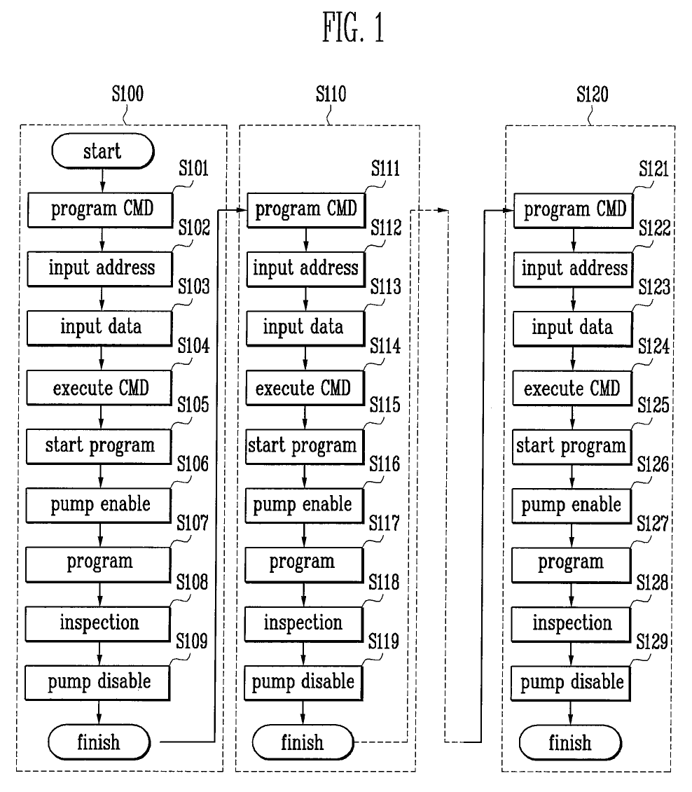

FIG. 2A is a flow chart showing a program operation for an initial page in a memory block of a flash memory device;

FIG. 2B is a flow chart showing a program operation for an intermediate page of the memory block;

FIG. 2C is a flow chart showing a program operation for a final page of the memory block; and

FIG. 2D is a flow chart showing a program operation of all pages of a memory block for a flash memory device according to an embodiment of the present invention.

### DESCRIPTION OF SPECIFIC EMBODIMENTS

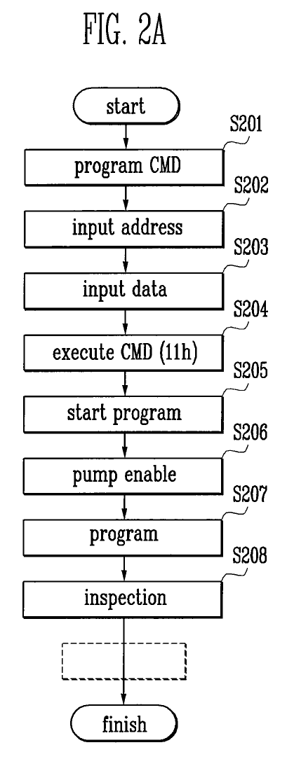

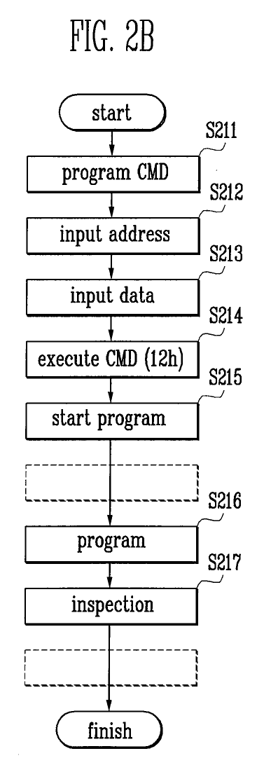

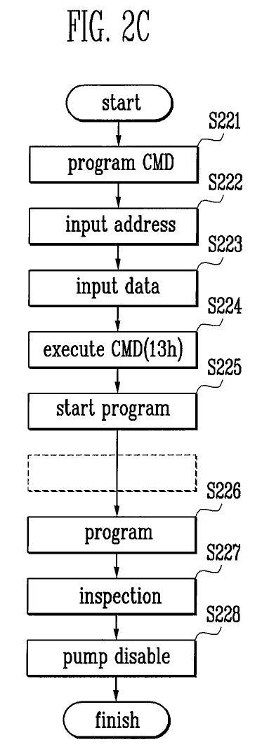

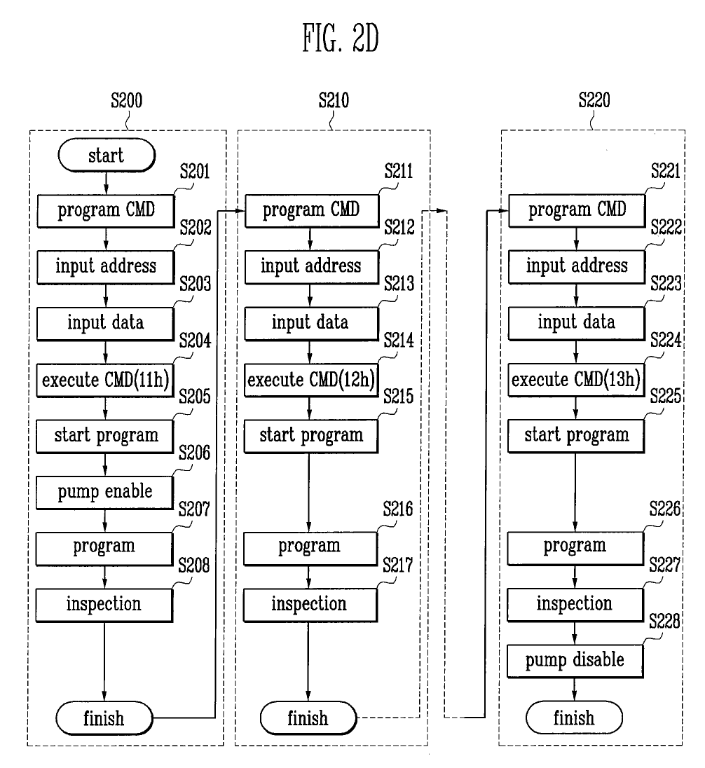

Referring to FIG. 2A, an operation order of a first execution command (CMD; 11h) to be input when programming a flash memory device is shown. The program command (CMD) for initiating a program operation on a page in a memory block of a flash memory device is input (S201). An address of a page to be programmed is input (S202). The first execution command is a program confirmation command for confirming that the program is input before initiating programming of the page.

The data to be programmed is input to a corresponding page (S203). The execution command 11h is then input to program the initial page in the memory block (S204).

When a controller of a memory device starts to program the initial page in accordance with the first execution command 11h (S205), a pump for applying a high voltage is enabled (S206).

The controller programs data on the initial page corresponding to the address input at step S202 using the high voltage output from the enabled pump (S207). The controller then inspects the programmed page to check for errors (S208).

The first execution command 11h completes operation when the inspection is finished. The pump that is enabled at step S206 continuously outputs a high voltage for the programming of subsequent pages in the memory block, as described below.

FIG. 2B is a flow chart showing a program operation for an intermediate page of the memory block.

After an initial page is programmed, a program command (CMD) for a subsequent intermediate page in the memory block and an address of the intermediate page to be programmed are input (S211, S212).

The data to be programmed on the intermediate page is input (S213). A second execution command (CMD; 12h) is input to initiate the programming of the intermediate page (S214, S215). When the program operation starts, further enablement of a pump is not necessary since the pump for producing a high voltage has already been enabled before programming the initial page. The intermediate page is then programmed and inspected (S216, S217).

The pump remains enabled such that subsequent pages of the memory block may be programmed. In other words, the intermediate program method (S211 to S217) is repeated for subsequent intermediate pages of the memory block while the pump remains enabled.

The flash memory is programmed on a page-by-page basis for the entire memory block until a final page of the memory block is programmed. The programming method then terminates automatically. Accordingly, when the programming of the intermediate pages, as described with reference to FIG. 2B, is complete, a program operation is performed on the final page of the memory block as described below.

FIG. 2C is a flow chart showing a program operation for a final page of the memory block.

Referring to FIG. 2C, to program the final page of a memory block, a program command and an address of the final page are input (S221, S222). Data to be programmed to the final page and a third execution command 13h are input (S223, S224).

The third execution command 13h is a command for programming the final page. When the program operation of the final page begins (S225), the final page is programmed and inspected using the high voltage from the enabled pump (S226, S227).

After inspection of the programmed final page is complete, the pump is disabled to terminate programming operations.

The first, second and third execution commands 11h, 12h, 13h may be changed automatically based on the input page address. In other words, when a program start command is received and the program command had not been executed previously, the first execution command 11h is input. For subsequent program operations, the second execution command 12h is input automatically when the input page address does not correspond to the address of a final page of the memory block.

When the input page address corresponds to the final page address of the memory block, the third execution command 13h is input automatically to disable the pump and terminate programming operations.

The programming of continuous pages in a memory block of a flash device in accordance with embodiments of the present invention will be described further below.

FIG. 2D is a flow chart showing a program operation of all pages of a memory block for a flash memory device according to an embodiment of the present invention.

Referring to FIG. 2D, the program operations of the pages in a memory block are categorized based on whether the page to be programmed is an initial page (S200), an intermediate page (S210) or a final page (S220).

When programming an initial page (S200), a program command (CMD) is input (S201), and an address of an initial page to be programmed is input (S202).

Data to be programmed is input to the initial page (S203).

An execution command (i.e., the first execution command 11h) is input to program the initial page.

A program of the initial page is executed by the first execution command 11h and the pump is enabled (S205, S206).

Programming and inspecting are performed using a high voltage from the pump (S207, S208). Thus, the initial program of a first page in a memory block is complete.

An intermediate page is then programmed (S210). A program command is input (S211). An address of the intermediate page to be programmed and corresponding program data are input (S212, S213). The input page address is not the address of the initial page or the final page in the memory block. The second execution command 12h is then input (S214).

When the second execution command 12h is input, the intermediate page is programmed and inspected using the high voltage output from the pump that is maintained as enabled (S216, S217). After the intermediate page is programmed, a program of a subsequent page still needs to be performed. Thus, the pump remains enabled.

Subsequent intermediate pages (S210) are programmed until an address of the final page of the memory block is input. When the address of the final page is input, programming of the final page is initiated.

When programming the final page (S220), a program command is input (S221) and an address of the final page is input (S222). The data to be programmed to the final page is input (S223) and the third execution command 13h is input (S224).

When the program of the final page is executed by the third execution command 13h (S225), the final page is programmed and inspected using the high voltage output from the pump (S226, S227). The pump is then disabled (S228) because all pages in the memory block are programmed.

As described above, when programming a memory block, execution commands are differently input for the initial, intermediate and final pages in the memory block such that the pump is enabled or disabled accordingly. As a result, unnecessary repetition of pump enablement/disablement can be avoided and program duration can be shortened.

According to the present invention, when programming a non-volatile memory device, each page of a memory block is executed continuously. The execution commands are differently input depending on whether the page to be programmed is an initial, intermediate or final page, and a pump is not unnecessarily enabled and disabled for each page of the memory block. Accordingly, memory block programming is simplified and the programming duration is shortened.

Although the technical spirit of the present invention has been concretely described in connection with the preferred embodiment, the scope of the present invention is not limited by the specific embodiments, but should be construed by the appended claims. Further, it should be understood by those skilled in the art that various changes and modifications can be made thereto without departing from the scope of the present invention.

What is claimed is:

1. A method of programming a non-volatile memory device, the method comprising:
enabling a pump in response to a first program confirm command, wherein the enabled pump generates a voltage;
programming an initial page of a memory block;
programming an intermediate page of the memory block subsequent to the initial page in response to a second program confirm command, wherein the pump remains enabled;
programming a final page of the memory block in response to a third program confirm command; and
disabling the pump after the final page is programmed.

2. A method of programming a non-volatile memory device according to claim 1, wherein programming the initial page of the memory block comprises:
inputting an initial program command, an address of the initial page, and program data;
inputting the first program confirm command in response to inputting the initial program command; and
programming the initial page using the voltage from the enabled pump.

3. A method of programming a non-volatile memory device according to claim 1, wherein programming the intermediate page comprises:
inputting a program command, an address of the intermediate page to be programmed, and program data;
inputting the second program confirm command; and
programming the intermediate page corresponding to the address in response to inputting the second program confirm command using the voltage provided by the enabled pump.

4. A method of programming for non-volatile memory device according to claim 1, wherein programming the final page comprises:
inputting a program command, an address of the final page and program data;
inputting the third program confirm command in response to inputting the address of the final page; and
programming the final page using the voltage provided by the enabled pump.

5. A method of programming a non-volatile memory device according to claim 1, wherein the first, second and third program confirm commands are input differently based on which page address is input.

6. A method of programming a non-volatile memory device according to claim 1, further comprising inspecting the programmed pages.
